(19) United States
(12) Patent Application Publication
(10) Pub. No.: US 2019/0157843 A1
(43) Pub. Date: May 23, 2019

(54) LASER LIGHT SOURCE UNIT

(71) Applicant: KOITO MANUFACTURING CO., LTD., Tokyo (JP)

(72) Inventor: Ryuho Sato, Shizuoka (JP)

(73) Assignee: KOITO MANUFACTURING CO., LTD., Tokyo (JP)

(21) Appl. No.: 16/193,638

(22) Filed: Nov. 16, 2018

(30) Foreign Application Priority Data
Nov. 17, 2017 (JP) 2017-221773

(51) Int. Cl. H01S 5/40; G02B 19/00; H01S 5/022; G02B 27/10; G02B 27/12

(52) U.S. Cl. CPC H01S 5/4012; G02B 19/0057; H01S 5/02248; H01S 5/02469; G02B 27/123; H01S 5/4075; G02B 27/106

(57) ABSTRACT

A laser light source unit configured to be able to irradiate, as combined light, laser light emitted from plural laser diodes toward front of the laser light source unit. The laser light source unit includes: plural first condensing lenses configured to condense the laser light emitted from each of the plural laser diodes; a microlens array disposed on a front side of the laser light source unit with respect to the plural first condensing lenses; and a second condensing lens disposed on the front side of the laser light source unit with respect to the microlens array. The microlens array and the second condensing lens are supported on a common lens holder. The microlens array is supported on the lens holder via an array holder. Plural through-holes through which light emitted from the plural first condensing lenses passes is formed in the array holder.

### CROSS-REFERENCE TO RELATED APPLICATIONS

This application is based on and claims priority under 35 USC 119 from Japanese Patent Application No. 2017-221773 filed on Nov. 17, 2017, the contents of which are incorporated herein by reference.

### TECHNICAL FIELD

The disclosure relates to a laser light source unit including a plurality of laser diodes.

### BACKGROUND ART

Conventionally, a laser light source unit is known which is configured to be able to irradiate, as combined light, laser light emitted from a plurality of laser diodes toward the front of the unit.

“JP-A-2014-186148” discloses a laser light source unit which includes a plurality of first condensing lenses for condensing laser light emitted from each of a plurality of laser diodes, a microlens array disposed on the front side of the unit with respect to the plurality of first condensing lenses, and a second condensing lens disposed on the front side of the unit.

When such a laser light source unit has a configuration in which the microlens array and the second condensing lens are supported on a common lens holder, it is possible to improve the accuracy of the positional relationship between the microlens array and the second condensing lens. At that time, when the microlens array is configured to be supported via an array holder, it is possible to easily form the microlens array from a material such as synthetic quartz which is inferior in workability but excellent in optical characteristics.

In the case of adopting such a configuration, the microlens array is supported on the array holder by adhesion fixation. At that time, it is desirable to secure sufficient support strength in order to secure the durability of the laser light source unit.

Therefore, there is no technique for providing a laser light source unit which includes a plurality of laser diodes and is capable of sufficiently securing the support strength of a microlens array.

### SUMMARY OF INVENTION

A laser light source unit configured to be able to irradiate, as combined light, laser light emitted from a plurality of laser diodes toward front of the laser light source unit. The laser light source unit includes: a plurality of first condensing lenses configured to condense the laser light emitted from each of the plurality of laser diodes; a microlens array disposed on a front side of the laser light source unit with respect to the plurality of first condensing lenses; and a second condensing lens disposed on the front side of the laser light source unit with respect to the microlens array. The microlens array and the second condensing lens are supported on a common lens holder, the microlens array is supported on the lens holder via an array holder, and a plurality of through-holes through which light emitted from the plurality of first condensing lenses passes is formed in the array holder.

It becomes possible to provide a laser light source unit which includes a plurality of laser diodes and is capable of sufficiently securing the support strength of a microlens array.

### BRIEF DESCRIPTION OF DRAWINGS

Exemplary embodiment(s) of the present invention will be described in detail based on the following figures, wherein:

FIG. 1 is a perspective view showing a laser light source unit according to an embodiment of the disclosure, together with a deflection mirror and a wavelength conversion element;

FIG. 2 is a sectional view taken along the line II-II in FIG. 1;

FIG. 3 is a sectional view taken along the line III-III in FIG. 1;

FIG. 4 is a perspective view separately showing an optical system of the laser light source unit;

FIG. 5 is an exploded perspective view showing a light source side sub-assembly of the laser light source unit, together with a set of heat sink and cooling fan;

FIG. 6A is a perspective view showing an assembling procedure of the light source side sub-assembly;

FIG. 6B is a perspective view showing an assembling procedure of the light source side sub-assembly;

FIG. 6C is a perspective view showing an assembling procedure of the light source side sub-assembly;

FIG. 6D is a perspective view showing an assembling procedure of the light source side sub-assembly;

FIG. 7A is a perspective view showing an assembling procedure of a light source module which is a component of the light source side sub-assembly;

FIG. 7B is a perspective view showing an assembling procedure of a light source module which is a component of the light source side sub-assembly;

FIG. 7C is a perspective view showing an assembling procedure of a light source module which is a component of the light source side sub-assembly;

FIG. 7D is a perspective view showing an assembling procedure of a light source module which is a component of the light source side sub-assembly;

FIG. 7E is a perspective view showing an assembling procedure of a light source module which is a component of the light source side sub-assembly;

FIG. 8 is an exploded perspective view showing a lens side sub-assembly of the laser light source unit, together with a light source holder which is a component of the light source side sub-assembly;

FIG. 9 is an exploded perspective view showing the lens side sub-assembly, as viewed from an angle different from FIG. 8;

FIG. 10A is a perspective view showing an assembling procedure of the lens side sub-assembly;

FIG. 10B is a perspective view showing an assembling procedure of the lens side sub-assembly;

FIG. 10C is a perspective view showing an assembling procedure of the lens side sub-assembly;

FIG. 10D is a perspective view showing an assembling procedure of the lens side sub-assembly;

FIG. 10E is a perspective view showing an assembling procedure of the lens side sub-assembly;

FIG. 11 is a view similar to FIG. 4, showing a first modification of the above embodiment; and

FIG. 12 is a view similar to FIG. 2, showing a second modification of the above embodiment.

### DESCRIPTION OF EMBODIMENTS

Hereinafter, an embodiment of the disclosure will be described with reference to the figures.

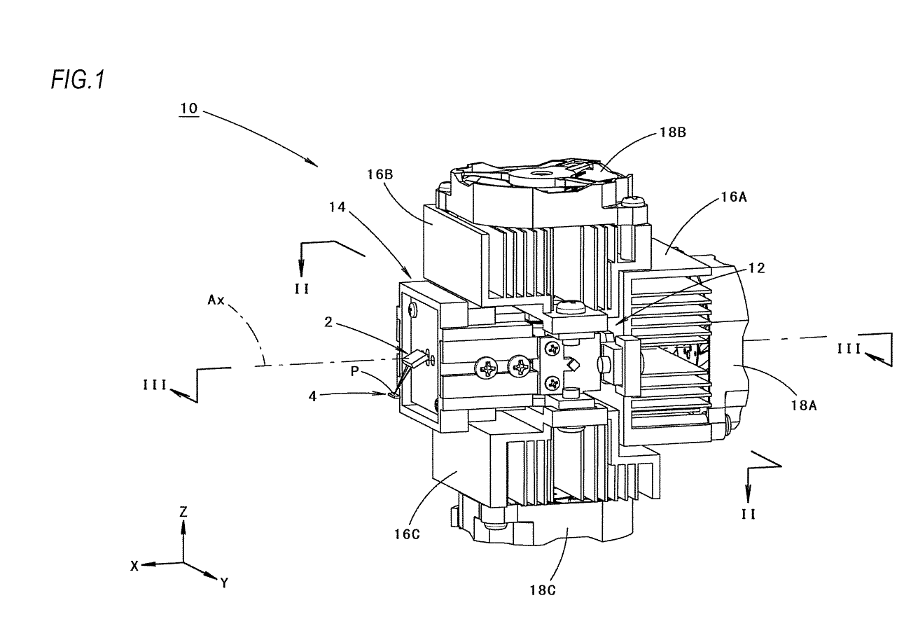

FIG. 1 is a perspective view showing a laser light source unit 10 according to an embodiment of the disclosure, together with a deflection mirror 2 and a wavelength conversion element 4.

In FIG. 1, the direction indicated by X is a “front direction” (i.e., “the front of the unit”) of the laser light source unit 10, the direction indicated by Y is a “left direction,” and the direction indicated by Z is an “upper direction.” This is also applied to other figures.

As shown in FIG. 1, the laser light source unit 10 according to the present embodiment has an irradiation reference axis Ax extending in a front and rear direction of the unit. Further, the laser light source unit 10 includes a light source side sub-assembly 12 disposed above the irradiation reference axis Ax, a lens side sub-assembly 14 disposed on the front side of the unit with respect to the light source side sub-assembly 12, and three sets of heat sinks 16A, 16B, 16C and cooling fans 18A, 18B, 18C arranged on the rear side of the unit and on both upper and lower sides of the unit with respect to the light source side sub-assembly 12.

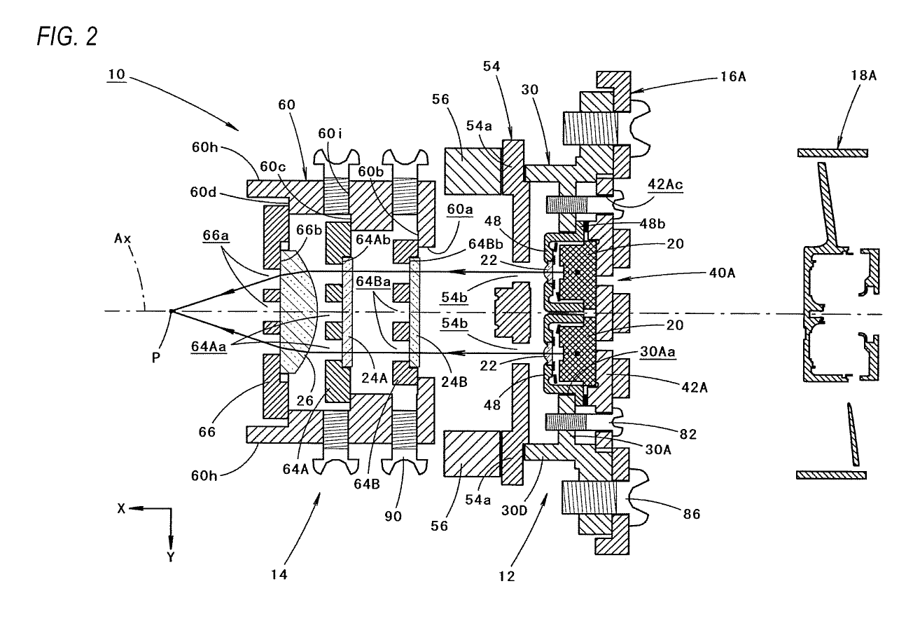

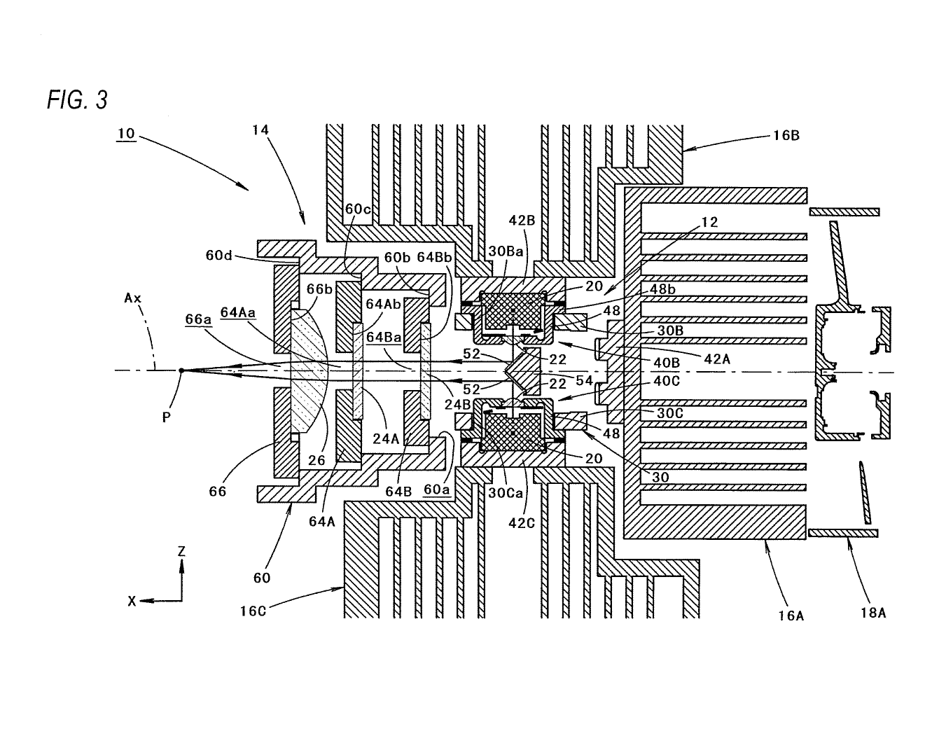

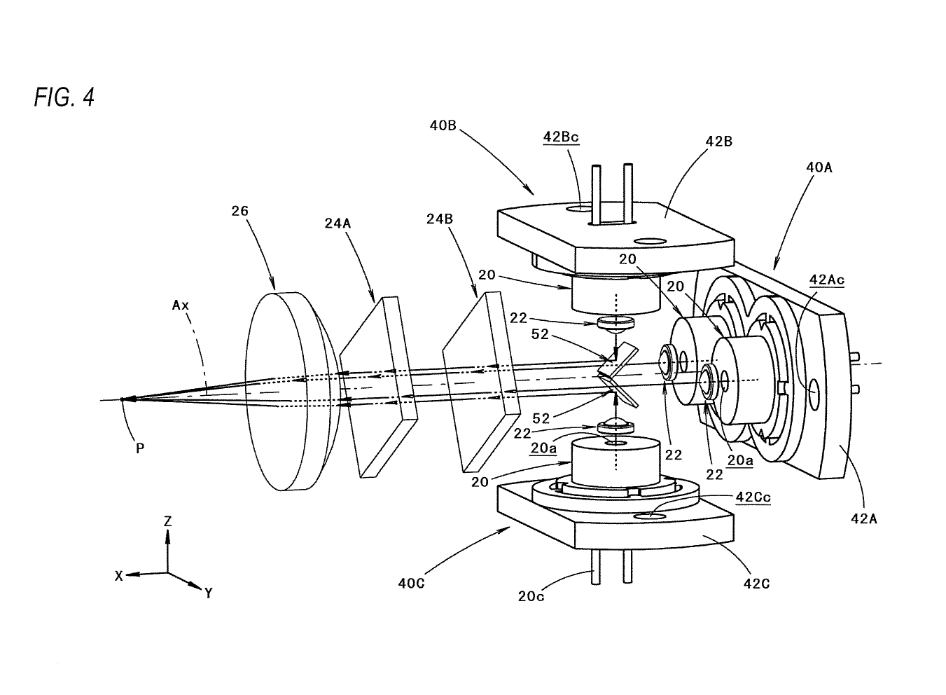

FIG. 2 is a sectional view taken along the line II-II in FIG. 1, and FIG. 3 is a sectional view taken along the line III-III in FIG. 1. Further, FIG. 4 is a perspective view separately showing an optical system of the laser light source unit 10.

As shown in these figures, the laser light source unit 10 is configured to be able to irradiate, as combined light, laser light emitted from four laser diodes 20 toward the front of the unit.

Specifically, the laser light source unit 10 includes, as its optical system, four first condensing lenses 22 for condensing laser light emitted from each of the four laser diodes 20, two microlens arrays 24A, 24B disposed on the front side of the unit with respect to the four first condensing lenses 22, and a second condensing lens 26 disposed on the front side of the unit with respect to the microlens arrays 24A, 24B.

Each of the four laser diodes 20 is a laser diode having a blue emission wavelength band (specifically, an emission wavelength of about 450 nm) and is arranged in a cross-shaped positional relationship around the irradiation reference axis Ax.

That is, two laser diodes 20 are arranged on both left and right sides of the irradiation reference axis Ax, and remaining two laser diodes 20 are arranged on both upper and lower sides of the irradiation reference axis Ax.

At that time, the pair of left and right laser diodes 20 is arranged toward the front of the unit in a positional relationship of bilateral symmetry with respect to the irradiation reference axis Ax, and the pair of upper and lower laser diodes 20 is arranged toward the irradiation reference axis Ax in a positional relationship of vertical symmetry with respect to the irradiation reference axis Ax on the front side of the unit than the pair of two left and right laser diodes 20.

The four first condensing lenses 22 are arranged in the vicinity of emission openings 20a of the four laser diodes 20 and function as a collimator lens for converting light emitted from the laser diodes 20 into substantially parallel light (i.e., parallel light or light close to parallel light).

The pair of left and right laser diodes 20 is supported, together with the pair of left and right first condensing lenses 22, by a common laser diode holder 42A, thereby forming a light source module 40A.

The pair of upper and lower laser diodes 20 is supported, together with the first condensing lenses 22, by laser diode holders 42B, 42C, respectively, thereby forming a pair of upper and lower light source modules 40B, 40C.

Three light source modules 40A, 40B, 40C are supported by a common light source holder 30, thereby forming a part of the light source side sub-assembly 12.

A pair of upper and lower mirrors 52 is disposed between the pair of upper and lower laser diodes 20 and the irradiation reference axis Ax. The pair of upper and lower mirrors 52 is arranged in a positional relationship of vertical symmetry with respect to the irradiation reference axis Ax and is adapted to specularly reflect the light emitted from the pair of upper and lower laser diodes 20 toward the front of the unit. The pair of upper and lower mirrors 52 is supported by the light source holder 30 via a mirror holder 54, thereby forming a part of the light source side sub-assembly 12.

A specific configuration of the light source side sub-assembly 12 will be described later.

The two microlens arrays 24A, 24B are arranged on the irradiation reference axis Ax in a state of being spaced apart from each other with a fixed interval in the front and rear direction of the unit. The two microlens arrays 24A, 24B are supported by a common lens holder 60 together with the second condensing lens 26.

At that time, the two microlens arrays 24A, 24B are supported by the lens holder 60 via array holders 64A, 64B, respectively, and the second condensing lens 26 is supported by the lens holder 60 via a second condensing lens holder 66, thereby forming the lens side sub-assembly 14.

In the lens side sub-assembly 14, the two microlens arrays 24A, 24B and the second condensing lens 26 form an integrator optical system.

A specific configuration of the lens side sub-assembly 14 will be also described later.

In the laser light source unit 10 according to the present embodiment, the laser light emitted from the pair of left and right laser diodes 20 and transmitted through the pair of left and right first condensing lenses 22, and the laser light emitted from the pair of upper and lower laser diodes 20 and transmitted through the pair of upper and lower first condensing lenses 22 and then specularly reflected by the pair of upper and lower mirrors 52 are incident on the second condensing lens 26 via the two microlens arrays 24A, 24B. The light emitted from the second condensing lens 26 is condensed at a point P on the irradiation reference axis Ax, which is a front focal point of the second condensing lens 26.

In FIG. 1, in order to show a concrete use example of the laser light source unit 10, the deflection mirror 2 and the wavelength conversion element 4 are additionally shown.

In this use example, the deflection mirror 2 is disposed on the irradiation reference axis Ax in the vicinity of the front of the laser light source unit 10, and the wavelength conversion element 4 is disposed upward at an obliquely lower front side of the deflection mirror 2. Further, the laser light from each of the laser diodes 20, which is emitted from the laser light source unit 10 toward the front of the unit, is specularly reflected downward by the deflection mirror 2 and condensed on the upper surface of the wavelength conversion element 4.

That is, in this use example, the point P at which the light emitted from the second condensing lens 26 is condensed is located on the upper surface of the wavelength conversion element 4.

At that time, in the laser light source unit 10, as described above, the two microlens arrays 24A, 24B and the second condensing lens 26 form the integrator optical system. Therefore, the intensity distribution of the laser light from each of the laser diodes 20, which is irradiated on the upper surface of the wavelength conversion element 4, has a substantially flat distribution over the entire beam diameter.

Subsequently, a specific configuration of the light source side sub-assembly 12 is described.

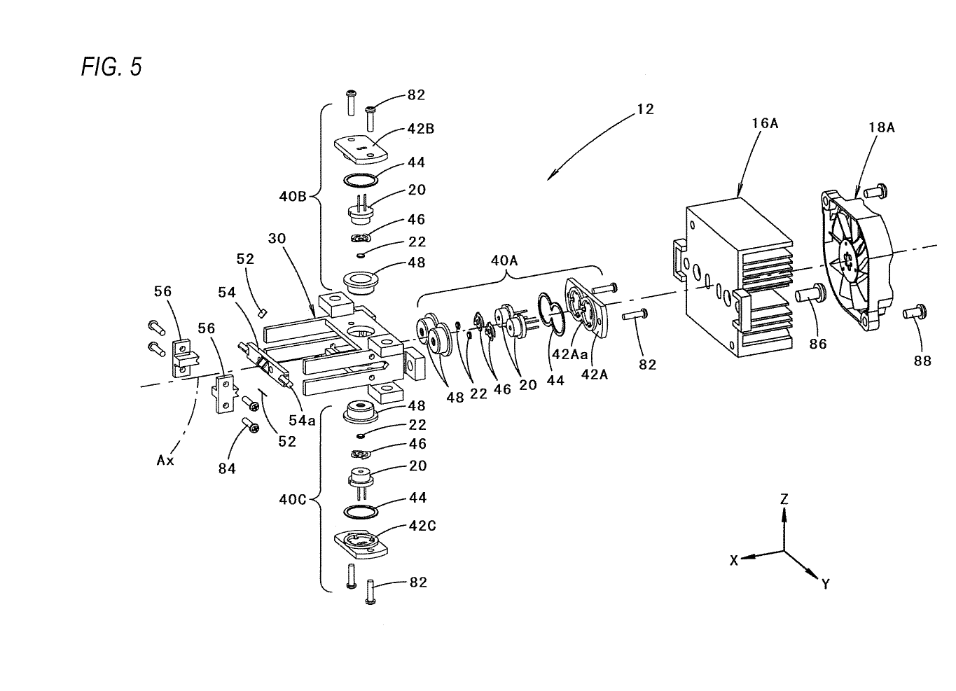

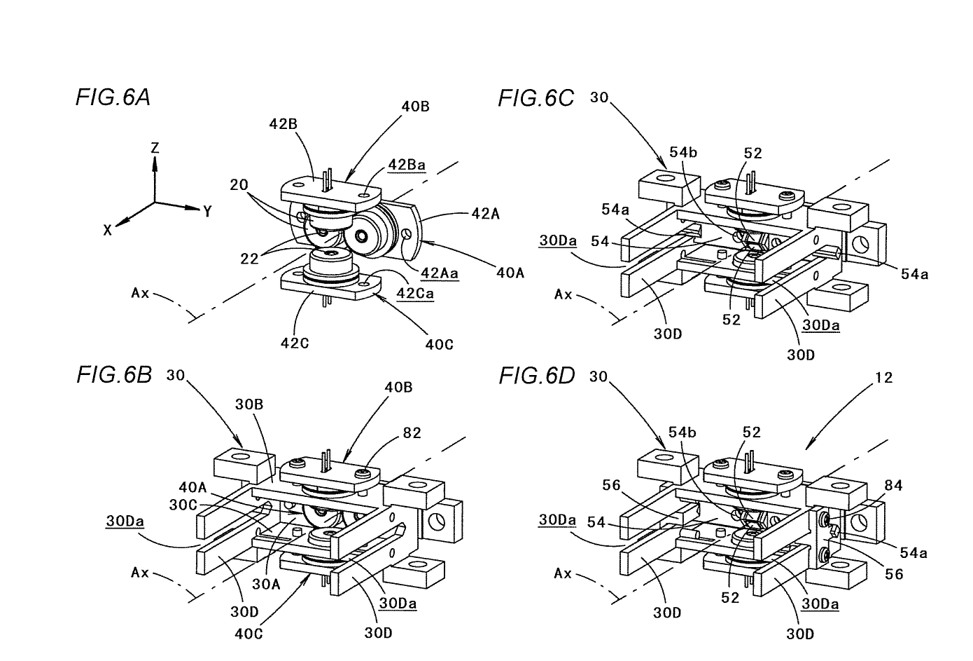

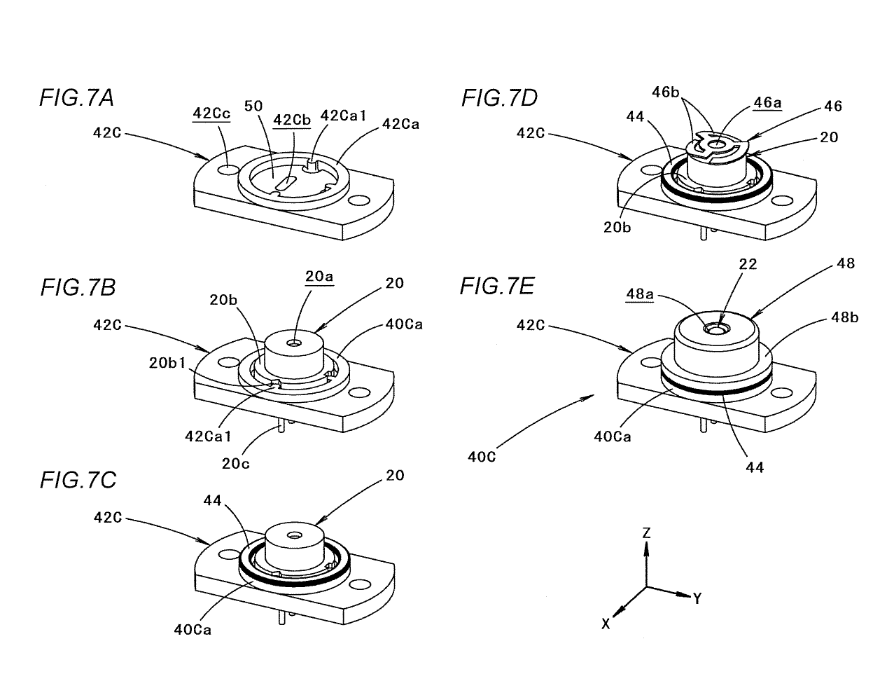

FIG. 5 is an exploded perspective view showing the light source side sub-assembly 12, together with the heat sink 16B and the cooling fan 18B arranged on the rear side of the unit. Further, FIGS. 6A to 6D are perspective views showing an assembling procedure of the light source side sub-assembly 12. Furthermore, FIGS. 7A to 7E are perspective views showing an assembling procedure of the light source module 40C located below the irradiation reference axis Ax.

First, a specific configuration of the light source module 40C is described.

In FIGS. 7A to 7E, the light source module 40C is assembled in the following manner. First, as shown in FIG. 7B, the laser diode 20 is mounted on the laser diode holder 42C shown in FIG. 7A. Then, as shown in FIG. 7C, an adhesive 44 is applied to the laser diode holder 42C. In this state, as shown in FIG. 7D, a lens holding spring 46 is placed on the laser diode 20. Then, as shown in FIG. 7E, a first condensing lens holder 48 on which the first condensing lens 22 is previously assembled is placed on the laser diode holder 42C.

As shown in FIG. 7A, the laser diode holder 42C has a configuration in which an annular protrusion 42Ca is formed on an upper surface of a laterally long plate-like member. In the laser diode holder 42C, positioning protrusions 42Ca1 are formed at three positions on an inner peripheral surface of the annular protrusion 42Ca. Further, a lead insertion hole 42Cb through which a lead 20c of the laser diode 20 is inserted is formed on the inner peripheral side of the annular protrusion 42Ca. Furthermore, a pair of screw insertion holes 42Cc is formed on both left and right sides of the annular protrusion 42Ca.

Further, heat transfer grease 50 is applied in advance on an upper surface of the laser diode holder 42C on the inner peripheral side of the annular protrusion 42Ca.

As shown in FIG. 7B, the laser diode 20 is mounted on the upper surface of the laser diode holder 42C on the inner peripheral side of the annular protrusion 42Ca. At that time, the positioning protrusions 42Ca1 of the laser diode holder 42C are engaged with notches 20b1 formed at three positions on an outer peripheral surface of an outer peripheral flange 20b of the laser diode 20, so that the laser diode 20 is positioned in the rotational direction.

As shown in FIG. 7C, the adhesive 44 is an ultraviolet-curable adhesive and is adapted to be applied on the upper surface of the annular protrusion 42Ca.

As shown in FIG. 7D, the lens holding spring 46 is a leaf spring in which an opening 46a larger than the emission opening 20a of the laser diode 20 is formed at the central portion and three elastic pieces 46b extending in a circumferential direction are formed at the outer peripheral portion. The lens holding spring 46 is placed on the laser diode 20 in a state where tip ends of the elastic pieces 46b are abutted against the upper surface of the laser diode 20.

As shown in FIG. 7E, the first condensing lens holder 48 has a top hat shape, and a circular opening 48a is formed at the center of the upper surface wall thereof. The first condensing lens 22 is adhered and fixed to the first condensing lens holder 48 at its outer peripheral edge in a state of being fitted into the opening 48a from the lower side.

Then, an outer peripheral flange 48b is formed at a lower end portion of an outer peripheral wall of the first condensing lens holder 48. The outer peripheral flange 48b of the first condensing lens holder 48 is adapted to be pressed against the adhesive 44 applied on the annular protrusion 42Ca of the laser diode holder 42C.

At that time, an inner peripheral edge of the outer peripheral flange 48b is abutted against the outer peripheral flange 20b of the laser diode 20, so that the pressing amount of the first condensing lens holder 48 against the adhesive 44 is defined. In this way, the positional relationship between the laser diode 20 and the first condensing lens holder 48 in the upper and lower direction is defined.

At this time, the lens holding spring 46 is abutted against the first condensing lens holder 48 at the outer peripheral portion of the opening 46a and is elastically deformed in the upper and lower direction. In this way, the first condensing lens 22 is constantly pressed against the first condensing lens holder 48 at its outer peripheral edge.

In a state where the first condensing lens holder 48 is placed on the annular protrusion 42Ca of the laser diode holder 42C via the adhesive 44 in this manner, the laser diode 20 is energized to emit light. By confirming the beam pattern of the laser light emitted from the emission opening 20a of the laser diode 20 and transmitted through the first condensing lens 22, the optimum position of the laser diode 20 in the horizontal plane is detected. In a state where the detection is completed, the adhesive 44 is cured by ultraviolet irradiation.

As a result, the assembly of the light source module 40C is completed.

As shown in FIGS. 5 and 6, the light source module 40B positioned above the irradiation reference axis Ax has the same configuration as the light source module 40C.

Further, the light source module 40A positioned on the rear side of the unit with respect to the light source holder 30 has the same configuration as the light source module 40C. Here, in the light source module 40A, the pair of left and right laser diodes 20 and the first condensing lens 22 are supported on the common laser diode holder 42A. Therefore, the shape of an annular protrusion 42Aa of the laser diode holder 42A, the application shape of the adhesive 44, and the outer shape of each first condensing lens holder 48 are partially different from those of the light source module 40C.

As shown in FIG. 6B, the light source holder 30 has a rear wall 30A extending along a vertical plane orthogonal to the irradiation reference axis Ax, an upper wall 30B and a lower wall 30C each extending horizontally from upper and lower end edges of the rear wall 30A toward the front of the unit, and a pair of left and right side walls 30D extending along a vertical plane parallel to the irradiation reference axis Ax from left and right end edges of the rear wall 30A toward the front of the unit. At that time, each side wall 30D is formed to extend to the front side of the unit than the upper wall 30B and the lower wall 30C.

As shown in FIGS. 2, 5 and 6, the light source module 40A is fixed to the rear wall 30A of the light source holder 30.

At that time, as shown in FIG. 2, the light source module 40A is abutted against the rear wall 30A of the light source holder 30 at its outer peripheral flange 48b in a state where the pair of left and right first condensing lens holders 48 is inserted into an opening 30Aa formed in the rear wall 30A of the light source holder 30 from the rear side of the unit. Further, by screwing a screw 82 inserted into a screw insertion hole 42Ac of the laser diode holder 42A against the rear wall 30A of the light source holder 30, the outer peripheral flanges 48b of the pair of left and right first condensing lens holders 48 are sandwiched by the rear wall 30A of the light source holder 30 and the laser diode holder 42A from both front and rear sides.

As shown in FIGS. 3, 5 and 6, the pair of upper and lower light source modules 40B, 40C are fixed to the upper wall 30B and the lower wall 30C of the light source holder 30, respectively.

At that time, as shown in FIG. 3, each of the light source modules 40B, 40C is abutted against the upper wall 30B/the lower wall 30C of the light source holder 30 at its outer peripheral flange 48b in a state where the first condensing lens holders 48 are inserted into openings 30Ba, 30Ca formed in the upper wall 30B/the lower wall 30C of the light source holder 30 from the upper side/lower side. Further, by screwing the screws 82 (see FIG. 5) inserted into screw insertion holes 42Bc, 40Bc (see FIG. 4) of the laser diode holders 42B, 42C against the upper wall 30B/the lower wall 30C of the light source holder 30, the outer peripheral flanges 48b of the first condensing lens holders 48 are sandwiched by the upper wall 30B/the lower wall 30C of the light source holder 30 and the laser diode holders 42A, 42C from both upper and lower sides.

As shown in FIG. 6B, a groove 30Da is formed in each of the side walls 30D of the light source holder 30. Each groove 30Da extends from the front end surface of each side wall to the vicinity of the rear wall 30A on the same horizontal plane as the irradiation reference axis Ax.

As shown in FIG. 6C, the mirror holder 54 is formed to extend in a direction orthogonal to the irradiation reference axis Ax on the same horizontal plane as the irradiation reference axis Ax. The mirror holder 54 is engaged with rear end portions of the grooves 30Da formed in the pair of left and right side walls 30D of the light source holder 30 at both left and right end portions 54a thereof. At that time, the mirror holder 54 is positioned in a state of being pressed against the rear end portions of both grooves 30Da. As shown in FIG. 6D, this positioning is performed by fixing a pair of left and right fixtures 56 to the pair of left and right side walls 30D of the light source holder 30 by screws 84 in a state where the pair of left and right fixtures 56 is abutted against both left and right end portions 54a of the mirror holder 54 from the front of the unit.

The left and right end portions 54a of the mirror holder 54 are set to have a rhombic vertical sectional shape in the front and rear direction of the unit. Further, the rear end portions of the grooves 30Da formed in the pair of left and right side walls 30D have the same vertical sectional shape as rear half surfaces of the left and right end portions 54a of the mirror holder 54. Furthermore, the portions of the pair of left and right fixtures 56 abutting against the left and right end portions 54a of the mirror holder 54 have the same vertical sectional shape as front half surfaces of the left and right end portions 54a of the mirror holder 54. In this way, the mirror holder 54 is prevented beforehand from rotating about a horizontal axis orthogonal to the irradiation reference axis Ax, and the pair of upper and lower mirrors 52 is accurately arranged in a predetermined direction.

As shown in FIG. 6C, the mirror holder 54 is provided with a pair of left and right openings 54b for prevent light emitted from the pair of left and right first condensing lenses 22 from being shielded.

As shown in FIG. 5, the heat sink 16A is fixed to the light source holder 30 from the rear side of the unit by screws 86, and the cooling fan 18A is fixed to the heat sink 16A from the rear side of the unit by screws 88. Similarly, remaining two sets of heat sinks 16B, 16C and cooling fans 18B, 18C shown in FIG. 1 are fixed to the light source holder 30 from both upper and lower sides by screws, respectively.

Subsequently, a specific configuration of the lens side sub-assembly 14 is described.

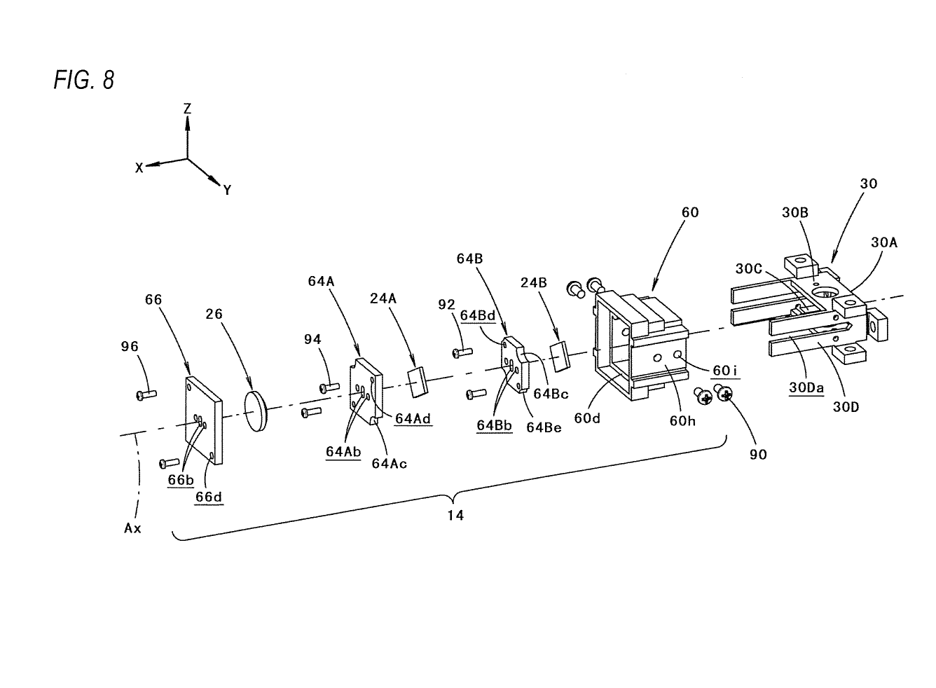

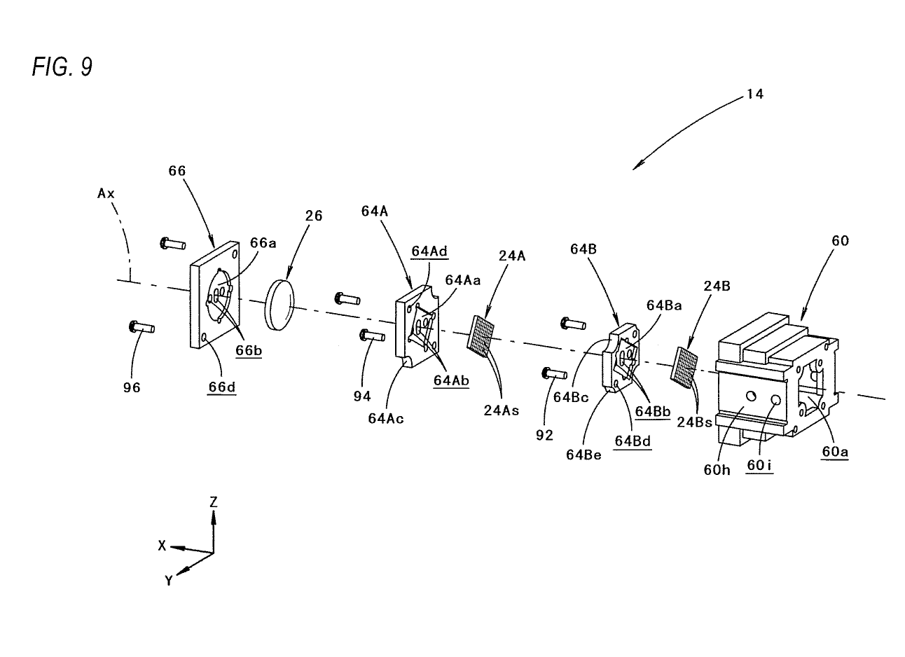

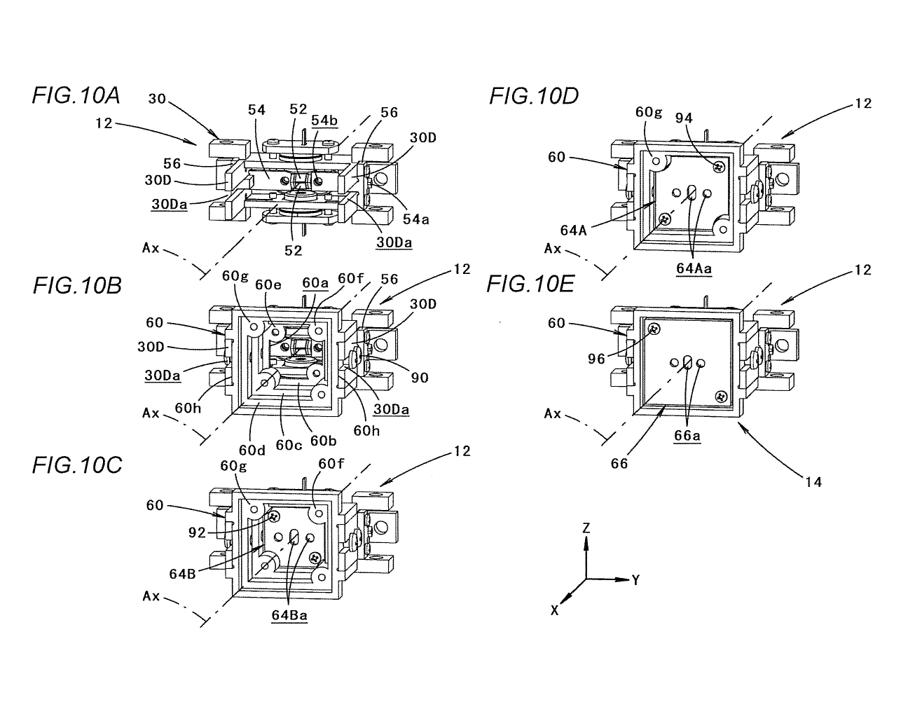

FIG. 8 is an exploded perspective view showing the lens side sub-assembly 14 together with the light source holder 30, and FIG. 9 is an exploded perspective view showing the lens side sub-assembly 14, as viewed from an angle different from FIG. 8. Further, FIGS. 10A to 10E are perspective views showing an assembling procedure of the lens side sub-assembly 14.

As shown in these figures, the lens holder 60 of the lens side sub-assembly 14 is formed as a cylindrical member extending in the front and rear direction of the unit. At that time, the lens holder 60 is formed such that the sectional shape along the vertical plane orthogonal to the irradiation reference axis Ax is set as a square shape and its inner diameter increases step by step toward the front of the unit.

Specifically, as shown in FIGS. 2, 3 and 10, a square opening 60a is formed in a rear end wall of the lens holder 60. A front surface of a square annual portion of the rear end wall located around the opening 60a serves as a holder support portion 60b for supporting an array holder 64B and is configured by a plane extending along the vertical plane orthogonal to the irradiation reference axis Ax.

A front surface of a square annular portion which is larger than the holder support portion 60b and located on the front side of the unit with respect to the holder support portion 60b serves as a holder support portion 60c for supporting the array holder 64A and is configured by a plane extending along the vertical plane orthogonal to the irradiation reference axis Ax.

Furthermore, a front surface of a square annular portion which is larger than the holder support portion 60c and located on the front side of the unit with respect to the holder support portion 60c serves as a holder support portion 60d for supporting the second condensing lens holder 66 and is configured by a plane extending along the vertical plane orthogonal to the irradiation reference axis Ax.

As shown in FIG. 10B, three pairs of bosses 60e, 60f, 60g are formed on an inner peripheral surface of the lens holder 60.

A pair of bosses 60e is formed to protrude into the opening 60a at two corners diagonally located on the opening 60a of the rear end wall. Each boss 60e is formed such that its front end surface is flush with the holder support portion 60b.

A pair of bosses 60f is formed to protrude into the holder support portion 60b and the opening 60a at remaining two corners diagonally located in the opening 60a of the rear end wall. Each boss 60f is formed such that its front end surface is flush with the holder support portion 60c.

A pair of bosses 60g is formed to protrude into the holder support portions 60b, 60c at the same two corners as the pair of bosses 60e. Each boss 60g is formed such that its front end surface is flush with the holder support portion 60d.

As shown in FIG. 9, both of the two microlens arrays 24A, 24B have the same configuration. Specifically, each of the microlens arrays 24A, 24B has a configuration in which a plurality of microlenses 24As, 24Bs are formed side by side in a lattice pattern on the rear surface of a transparent plate having a square outer shape.

The array holder 64B positioned on the rear side of the unit is configured as a plate-like member having an outer shape in which a part of the square is missing. On the rear surface of the array holder 64B, a square recess 64Ba having an outer shape substantially equal in size to the microlens array 24B is formed around the irradiation reference axis Ax. The recess 64Ba is formed in a state of being rotated by a constant angle (e.g., about 30°) around the irradiation reference axis Ax with respect to the array holder 64B in the upright state.

In the array holder 64B, three through-holes 64Bb penetrating the array holder 64B in the front and rear direction of the unit at the position of the recess 64Ba are formed in a state of being aligned on the same horizontal plane.

Of the three through-holes 64Bb, the through-hole 64Bb positioned at the center is formed on the irradiation reference axis Ax, and the two through-holes 64Bb positioned on both sides of the through-hole 64Bb are formed in the positional relationship of bilateral symmetry with respect to the irradiation reference axis Ax. At that time, the opening shape of the through-hole 64Bb positioned at the center is set to a vertically elongated oval shape, and the opening shapes of the pair of left and right through-holes 64Bb are set to circular shapes.

The through-hole 64Bb positioned at the center is a through-hole through which light emitted from the pair of upper and lower laser diodes 20 passes. This through-hole 64Bb has a size that does not shield the laser light which has become substantially parallel light by each of the first condensing lenses 22. Further, each of the pair of left and right through-holes 64Bb is a through-hole through which light emitted from the pair of left and right laser diodes 20 passes. Each of the pair of left and right through-holes 64Bb has a size that does not shield the laser light which has become substantially parallel light by each of the first condensing lenses 22.

The array holder 64B has an outer shape slightly smaller than an outer peripheral shape of the holder support portion 60b. In this way, adjustment clearance for adjusting the position of the array holder 64B in a direction orthogonal to the irradiation reference axis Ax is secured.

In the array holder 64B, arcuate notches 64Bc are formed at two corners located in the diagonal relationship. At remaining two corners of the array holder 64B, screw insertion holes 64Bd and arcuate notches 64Be smaller than the notches 64Bc are formed. At that time, the pair of notches 64Bc is formed to avoid interference with the pair of bosses 60f, and the pair of notches 64Be is formed to avoid interference with the pair of bosses 60g.

The microlens array 24B is adhered and fixed to the array holder 64B in a state of being fitted into the recess 64Ba of the array holder 64B. At that time, adhesive is applied to the area of the recess 64Ba away from the three through-holes 64Bb, so that the adhesive does not inadvertently flow into the through-holes 64Bb.

The array holder 64A positioned on the front side of the unit is also configured as a plate-like member having an outer shape in which a part of the square is missing. The array holder 64A has a configuration in which a recess 64Aa and three through-holes 64Ab are formed similarly to the array holder 64B.

The array holder 64A has an outer shape slightly smaller than an outer peripheral shape of the holder support portion 60c. In this way, adjustment clearance for adjusting the position of the array holder 64A in a direction orthogonal to the irradiation reference axis Ax is secured.

In the array holder 64A, arcuate notches 64Ac are formed at two corners located in the diagonal relationship. The two notches 64Ac are formed at two corners corresponding to the notches 64Be formed in the array holder 64B in order to avoid interference with the pair of bosses 60g. Screw insertion holes 64Ad are formed at remaining two corners of the array holder 64A.

The microlens array 24A is adhered and fixed to the array holder 64A in a state of being fitted into the recess 64Aa of the array holder 64A. At that time, adhesive is applied to the area of the recess 64Aa away from the three through-holes 64Ab, so that the adhesive does not inadvertently flow into the through-holes 64Ab.

The second condensing lens holder 66 is configured as a plate-like member that has a square outer shape slightly smaller than an outer peripheral shape of the holder support portion 60d. In this way, adjustment clearance for adjusting the position of the second condensing lens holder 66 in a direction orthogonal to the irradiation reference axis Ax is secured.

On the rear surface of the second condensing lens holder 66, a circular recess 66a having an outer shape substantially equal in size to the second condensing lens 26 is formed around the irradiation reference axis Ax.

In the recess 66a of the second condensing lens holder 66, three through-holes 66b penetrating the second condensing lens holder 66 in the front and rear direction of the unit are formed in a state of being aligned on the same horizontal plane.

The shapes of the three through-holes 66b are the same as those of the three through-holes 66b of the array holder 64B. Here, the through-hole 66b positioned at the center is formed on the irradiation reference axis Ax, but the two through-holes 66b positioned on both sides thereof are formed at positions closer to the irradiation reference axis Ax than the two through-holes 64Bb in the array holder 64B in order not to shield the laser light emitted as convergent light from the second condensing lens 26.

In the second condensing lens holder 66, screw insertion hole 66d are formed at two corners corresponding to the notches 64Ac formed in the array holder 64A.

The second condensing lens 26 is adhered and fixed to the second condensing lens holder 66 in a state of being fitted into the recess 66a of the second condensing lens holder 66. At that time, adhesive is applied to the area of the recess 66a away from the three through-holes 66b, so that the adhesive does not inadvertently flow into the through-holes 66b.

As shown in FIG. 8, a pair of left and right rail grooves 60h is formed on the outer surfaces of both side walls of the lens holder 60.

Each of the rail grooves 60h has a configuration in which a pair of upper and lower protrusions extending in the front and rear direction of the unit with respect to the vertical plane parallel to the irradiation reference axis Ax are formed. At that time, in each of the rail grooves 60h, the distance between the pair of upper and lower protrusions is set to substantially the same value as the width of each side wall 30D of the light source holder 30 in the upper and lower direction. Further, on the center portion in the upper and lower direction of each of the rail grooves 60h, screw holes 60i are formed at two positions in the front and rear direction.

Further, the rail grooves 60h of the lens holder 60 are engaged with the side walls 30D of the light source holder 30 and slid in the front and rear direction of the unit, so that the positional relationship between the light source holder 30 and the second condensing lens holder 66 in the front and rear direction of the unit can be adjusted. At that time, when screws 90 are previously tightened to the screw holes 60i of the lens holder 60 halfway, the positioning after adjusting the positional relationship between the light source holder 30 and the second condensing lens holder 66 in the front and rear direction of the unit can be efficiently performed by additionally tightening the screws 90.

The assembly of the array holders 64B, 64A and the second condensing lens holder 66 to the lens holder 60 is performed as follows.

First, as shown in FIG. 10A, the light source side sub-assembly 12 is assembled beforehand.

Subsequently, as shown in FIG. 10B, the rail grooves 60h of the lens holder 60 and the side walls 30D of the light source holder 30 are engaged. At that time, by lightly fastening the screws 90 engaged with the grooves 30Da of the side walls 30D, the lens holder 60 is temporarily fixed to the light source holder 30.

Subsequently, as shown in FIG. 10C, in a state where an ultraviolet-curable adhesive (not shown) is applied on the rear surface of the array holder 64B on which the microlens array 24B is mounted beforehand, the array holder 64B is inserted into the lens holder 60 from the front side of the unit and pressed against the holder support portion 60b.

In this state, the four laser diodes 20 are energized to confirm the irradiation pattern of light emitted from the microlens array 24B, and the optimum positions of the laser diodes in a direction orthogonal to the irradiation reference axis Ax are detected. After this detection, the adhesive is cured by ultraviolet irradiation to fix the array holder 64B to the holder support portion 60b of the lens holder 60. Then, screws 92 are inserted into the screw insertion holes 64Bd of the array holder 64B and fastened to the bosses 60e of the lens holder 60, so that the array holder 64B is mechanically fixed to the lens holder 60.

Thereafter, the screws 90 are loosened to make the lens holder 60 slidable in the front and rear direction of the unit with respect to the light source holder 30. Then, the four laser diodes 20 are energized to confirm the irradiation pattern of light emitted from the microlens array 24B, and the optimum position of the lens holder 60 to the light source holder 30 in the front and rear direction of the unit is detected. After this detection, the screws 90 are tightened to fully fix the lens holder 60 to the light source holder 30.

Subsequently, as shown in FIG. 10D, in a state where an ultraviolet-curable adhesive (not shown) is applied on the rear surface of the array holder 64A on which the microlens array 24A is mounted beforehand, the array holder 64A is inserted into the lens holder 60 from the front side of the unit and pressed against the holder support portion 60c.

In this state, the four laser diodes 20 are energized to confirm the irradiation pattern of light emitted from the microlens array 24A, and the optimum positions of the laser diodes in a direction orthogonal to the irradiation reference axis Ax are detected. After this detection, the adhesive is cured by ultraviolet irradiation to fix the array holder 64A to the holder support portion 60c of the lens holder 60. Then, screws 94 are inserted into the screw insertion holes 64Ad of the array holder 64A and fastened to the bosses 60f of the lens holder 60, so that the array holder 64A is mechanically fixed to the lens holder 60.

Finally, as shown in FIG. 10E, in a state where an ultraviolet-curable adhesive (not shown) is applied on the rear surface of the second condensing lens holder 66 on which the second condensing lens 26 is mounted beforehand, the second condensing lens holder 66 is inserted into the lens holder 60 from the front side of the unit and pressed against the holder support portion 60d.

In this state, the four laser diodes 20 are energized to confirm the irradiation pattern of light emitted from the second condensing lens 26, and the optimum positions of the laser diodes in a direction orthogonal to the irradiation reference axis Ax are detected. After this detection, the adhesive is cured by ultraviolet irradiation to fix the second condensing lens holder 66 to the holder support portion 60d of the lens holder 60. Then, screws 96 are inserted into the screw insertion holes 66d of the second condensing lens holder 66 and fastened to the bosses 60g of the lens holder 60, so that the second condensing lens holder 66 is mechanically fixed to the lens holder 60.

Next, the operational effect of the present embodiment is described.

The laser light source unit 10 according to the present embodiment includes the four first condensing lenses 22 for condensing the laser light emitted from each of the four laser diodes 20, the two microlens arrays 24A, 24B disposed on the front side of the unit with respect to the four first condensing lenses 22, and the second condensing lens 26 disposed on the front side of the unit. Therefore, the laser light source unit 10 can irradiate, as combined light, the laser light emitted from the four laser diodes 20 toward the front of the unit.

At that time, since the two microlens arrays 24A, 24B and the second condensing lens 26 are supported on the common lens holder 60, it is possible to improve the accuracy of the positional relationship therebetween. Moreover, since the two microlens arrays 24A, 24B are respectively supported on the lens holder 60 via the array holders 64A, 64B, it is possible to easily form the microlens arrays from a material such as synthetic quartz which is inferior in workability but excellent in optical characteristics. In this way, it is possible to broaden the range of selection for the type of each laser diode 20 and its output. That is, for example, as in the present embodiment, a laser diode having a blue emission wavelength band can be used as each of the laser diodes 20.

In addition, the three through-holes 64Ab, 64Bb through which the light emitted from the four first condensing lenses 22 passes are formed in each of the array holders 64A, 64B. Therefore, as compared to the case where each of the array holders is configured by a general annular member in which a single circular opening is formed, sufficient bonding margin can be secured when respectively bonding the microlens arrays 24A, 24B to the array holders 64A, 64B. In this way, it is possible to sufficiently secure the support strength of each of the microlens arrays 24A, 24B.

As described above, according to the present embodiment, in the laser light source unit 10 including the four laser diodes 20, it is possible to sufficiently secure the support strength of each of the microlens arrays 24A, 24B.

Further, according to the present embodiment, the three through-holes 64Ab, 64Bb are formed in each of the array holders 64A, 64B, so that it is possible to efficiently remove stray light included in the light emitted from the four first condensing lenses 22. In particular, even when some of the four first condensing lenses 22 are detached, the occurrence of the stray light can be suppressed to the minimum.

Moreover, in the lens holder 60, adjustment clearance for adjusting the positions of the array holders 64A, 64B in a direction orthogonal to the front and rear direction of the unit is provided in the holder support portions 60c, 60b for supporting the array holders 64A, 64B. Therefore, the microlens arrays 24A, 24B can be aligned in a state where the microlens arrays 24A, 24B supported on the array holders 64A, 64B are positioned in the front and rear direction of the unit.

Moreover, since the array holders 64A, 64B are supported on the holder support portions 60c, 60b by adhesion fixation with an ultraviolet-curable adhesive and screw fastening, the microlens arrays 24A, 24B can be securely supported by the lens holder 60.

In the present embodiment, the second condensing lens 26 is also supported on the lens holder 60 via the second condensing lens holder 66, so that it is possible to easily form the second condensing lens from a material such as synthetic quartz which is inferior in workability but excellent in optical characteristics.

Further, the three through-holes 66b are also formed in the second condensing lens holder 66, so that it is possible to more efficiently suppress the occurrence of stray light.

Furthermore, in the lens holder 60, adjustment clearance for adjusting the position of the second condensing lens 26 in a direction orthogonal to the front and rear direction of the unit is also provided in the holder support portion 60d for supporting the second condensing lens holder 66. Therefore, the second condensing lens 26 can be aligned in a state where the second condensing lens 26 supported on the second condensing lens holder 66 are positioned in the front and rear direction of the unit.

Moreover, since the second condensing lens holder 66 is supported on the holder support portion 60d by adhesion fixation with an ultraviolet-curable adhesive and screw fastening, the second condensing lens holder 66 can be securely supported by the lens holder 60.

In the present embodiment, four sets of laser diodes 20 and first condensing lenses 22 are supported on the common light source holder 30, so that the accuracy of the positional relationship therebetween can be improved. Moreover, since the lens holder 60 is fixed to the light source holder 30 in a state of being engaged with the light source holder 30 so as to be slidable in the front and rear direction of the unit, it is possible to improve the accuracy of the positional relationship between the two microlens arrays 24A, 24B and the second condensing lens 26 supported on the lens holder 60 and the four sets of laser diodes 20 and first condensing lenses 22 supported on the light source holder 30.

Furthermore, in the present embodiment, the four laser diodes 20 are arranged in a cross-shaped positional relationship around the irradiation reference axis Ax of the laser light source unit 10, and the pair of mirrors 52 is disposed on both upper and lower sides of the irradiation reference axis Ax. Further, the pair of left and right laser diodes 20 is disposed toward the front of the unit, and the pair of upper and lower laser diodes 20 is disposed toward the pair of upper and lower mirrors 52. Therefore, the following operational effects can be obtained.

That is, the three through-holes 64Ab, 64Bb in each of the array holders 64A, 64B can be arranged in the vicinity of the irradiation reference axis Ax. Therefore, it is possible to secure larger adhesion margin for adhering the microlens arrays 24A, 24B, and the support strength of the microlens arrays 24A, 24B can be further improved.

Further, in the present embodiment, the pair of upper and lower mirrors 52 is fixed to the light source holder 30, so that the four sets of laser diodes 20 and first condensing lenses 22 can be easily arranged with good space efficiency.

At that time, since the pair of upper and lower mirrors 52 is supported on the light source holder 30 via the mirror holder 54, it is possible to increase the degree of freedom in the arrangement of the pair of upper and lower mirrors 52.

In the above embodiment, the pair of left and right laser diodes 20 is arranged toward the front of the unit, and the pair of upper and lower laser diodes 20 is arranged toward the pair of upper and lower mirrors 52. However, the pair of upper and lower laser diodes 20 may be arranged toward the front of the unit, and the pair of left and right laser diodes 20 may be arranged toward the pair of left and right mirrors 52. Also in such a case, it is possible to obtain substantially the same operational effect as in the case of the above embodiment.

In the above embodiment, the laser light source unit 10 includes four laser diodes 20. However, the laser light source unit 10 may include three or less laser diodes 20 or five or more laser diodes 20.

In the above embodiment, two microlens arrays 24A, 24B are disposed. However, a single microlens array may be disposed.

Next, modifications of the above embodiment are described.

First, a first modification of the above embodiment is described.

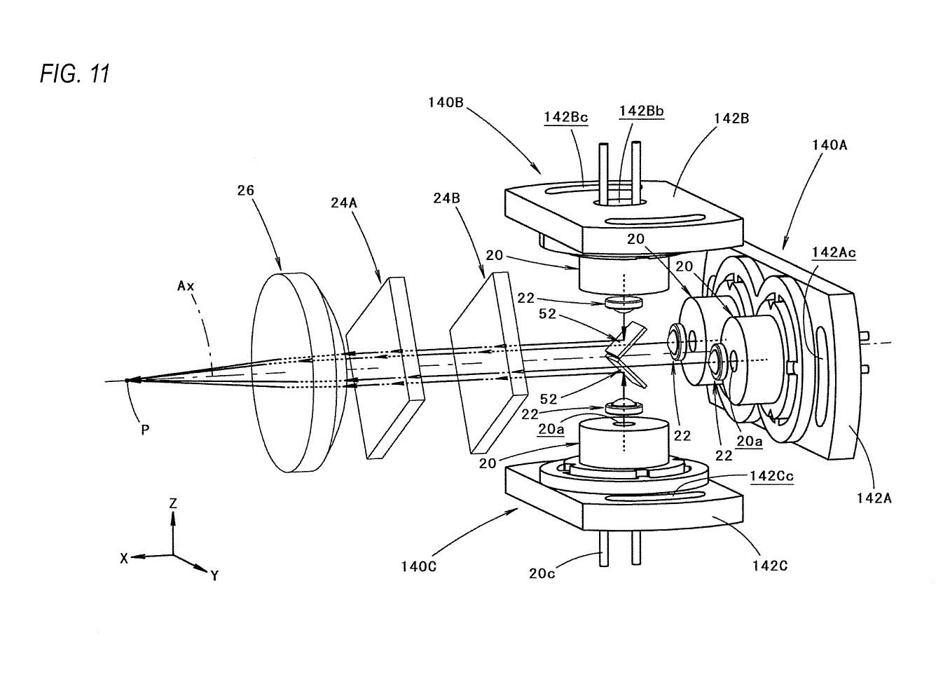

FIG. 11 is a view similar to FIG. 4, showing an optical system of a laser light source unit of the present modification.

As shown in FIG. 11, a basic configuration of the present modification is similar to that of the above embodiment. However, the present modification is partially different from the above embodiment in the configurations of three light source modules 140A, 140B, 140C.

Specifically, a basic configuration of each of the light source modules 140A, 140B, 140C in the present modification is similar to that in the above embodiment. However, the shapes of screw insertion holes 142Ac, 142Bc, 142Cc formed in laser diode holders 142A, 142B, 142C of the light source modules 140A, 140B, 140C are different from those in the above embodiment.

Specifically, in each of the light source modules 40A, 40B, 40C in the above embodiment, each of the screw insertion holes 42Ac, 42Bc, 42Cc formed in the laser diode holders 42A, 42B, 42C has a circular opening shape. On the contrary, in each of the light source modules 140A, 140B, 140C in the present modification, each of the screw insertion holes 142Ac, 142Bc, 142c formed in the laser diode holders 142A, 142B, 142C has an oval opening shape extending in an arc shape around the center axis of each of the light source modules 140A, 140B, 140C.

At that time, the center axis of the light source module 140A is an axis extending in the front and rear direction of the unit so as to pass through the middle point positions of the emission openings 20a of the pair of left and right laser diodes 20, and the center axes of the light source modules 140B, 140C are axes extending in the upper and lower direction so as to pass through the middle point positions of the emission openings 20a of the laser diodes 20.

Further, in the present modification, a lead insertion hole 142Bb formed in the laser diode holder 142B of the light source module 140B is formed to have an opening diameter larger than that in the above embodiment. This point also applies to the other light source modules 140A, 140C.

Also in the case of adopting the configuration of the present modification, it is possible to obtain substantially the same operational effect as in the case of the above embodiment.

Further, by adopting the configuration of the present modification, each of the light source modules 140A, 140B, 140C can be rotated to some extent about the center axis of each of the light source modules 140A, 140B, 140C when assembling the light source modules 140A, 140B, 140C to the light source holder 30 (see FIG. 6). In this way, it is possible to adjust the angle of the beam pattern of the light emitted from the laser diode 20.

Next, a second modification of the above embodiment is described.

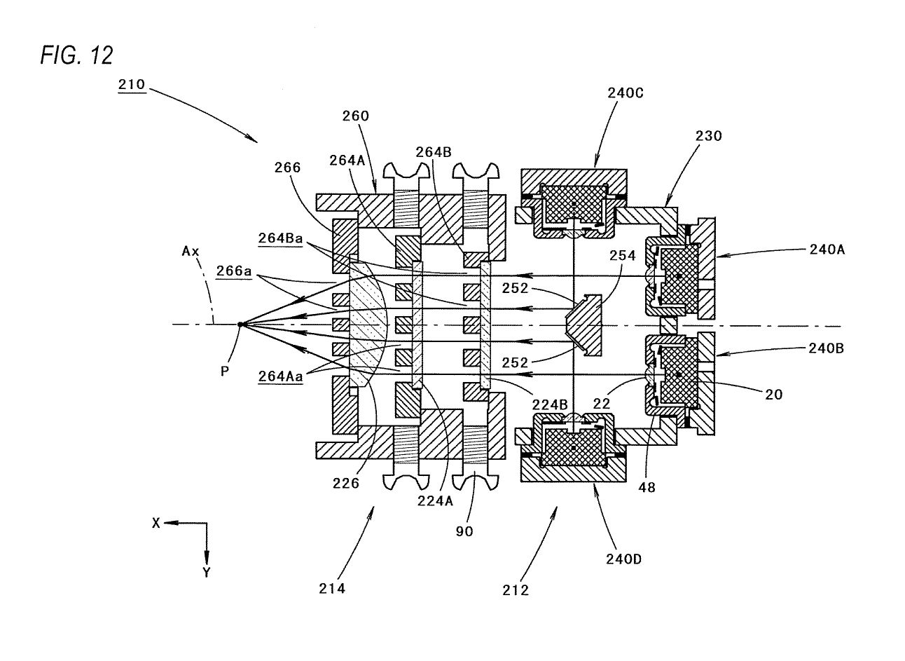

FIG. 12 is a view similar to FIG. 2, showing a laser light source unit 210 of the present modification.

As shown in FIG. 12, a basic configuration of the present modification is similar to that of the above embodiment. However, the present modification is different from the above embodiment in the configuration of a light source side sub-assembly 212. Along with this, the present modification is partially different from the above embodiment in the configuration of a lens side sub-assembly 214.

That is, the light source side sub-assembly 212 of the present modification has a configuration in which four light source modules 240A, 240B, 240C, 240D are arranged on the same horizontal plane including the irradiation reference axis Ax.

At that time, two light source modules 240A, 240B are arranged toward the front of the unit in the positional relationship of vertical symmetry on both left and right sides of the irradiation reference axis Ax, and remaining two light source modules 240C, 240D are arranged toward the irradiation reference axis Ax in the positional relationship of bilateral symmetry on the front side of the unit than the two light source modules 240A, 240B.

The four light source modules 240A to 240D are supported on a common light source holder 230.

A pair of left and right mirrors 252 is disposed between the pair of left and right light source modules 240C, 240D and the irradiation reference axis Ax. The pair of left and right mirrors 252 is arranged in the positional relationship of bilateral symmetry with respect to the irradiation reference axis Ax and is adapted to specularly reflect light emitted from the pair of left and right light source modules 240C, 240D toward the front of the unit. The pair of left and right mirrors 252 is supported on the light source holder 230 via a mirror holder 254.

On the other hand, the lens side sub-assembly 214 of the present modification also has a configuration in which two microlens arrays 224A, 224B are supported on a lens holder 260 via array holders 264A, 264B, respectively, and a second condensing lens 226 is supported on the lens holder 260 via a second condensing lens holder 266, similar to that of the above embodiment.

Here, four through-holes 264Aa, 264Ba are formed side by side on the same horizontal plane as the irradiation reference axis Ax in each of the array holders 264A, 264B, and four through-holes 266a are formed side by side on the same horizontal plane as the irradiation reference axis Ax in the second condensing lens holder 266. In this way, the laser light emitted from each of the light source modules 240A to 240D is adapted to pass through the through-holes.

Meanwhile, in the present modification, the heat sink and the cooling fan (not shown) common to the four light source modules 240A to 240D are arranged above the light source holder 230.

Also in the case of adopting the configuration of the present modification, it is possible to obtain substantially the same operational effect as in the case of the above embodiment.

Further, by adopting a configuration in which the four light source modules 240A to 240D are arranged on the same plane as in the present modification, it is possible to simplify the structure of the light source side sub-assembly 212. Furthermore, by adopting such a configuration, the heat sink and the cooling fan attached to the light source side sub-assembly 212 can be shared, and the number of the heat sink and the cooling fan to be installed can be reduced.

Meanwhile, the numerical values described as the specifications in the above embodiment and its modifications are merely examples, and it goes without saying that these numerical values may be set to other values as appropriate.

Further, the disclosure is not limited to the configurations described in the above embodiment and its modifications, and a configuration added with other various changes can be adopted. The aforementioned embodiment is summarized as follows.

The “laser light source unit” may be configured to irradiate, as combined light or single light, only the laser light emitted from some of a plurality of laser diodes toward the front of the unit, so long as the laser light source unit is configured to be able to irradiate, as combined light, laser light emitted from a plurality of laser diodes toward the front of the unit.

The “front of the unit” means the front of the laser light source unit.

The “plurality of laser diodes” may be the same kind of laser diodes (e.g., a blue laser or the like) or different kinds of laser diodes (e.g., a combination of a laser of three colors of RGB and an infrared laser).

The specific shape and specific arrangement and the like of each microlens in the “microlens array” are not particularly limited, so long as a plurality of microlenses is formed side by side on the surface of a transparent plate.

The specific arrangement of a plurality of through-holes and the specific shape of each through-hole in the “array holder” are not particularly limited, so long as a plurality of through-holes through which light emitted from a plurality of first condensing lenses passes is formed in the array holder. At that time, the “plurality of through-holes” may or may not be equal to the number of “a plurality of first condensing lenses.”

The laser light source unit according to the disclosure includes a plurality of first condensing lenses configured to condense laser light emitted from each of a plurality of laser diodes; a microlens array disposed on the front side of the laser light source unit with respect to the plurality of first condensing lenses; and a second condensing lens disposed on the front side of the laser light source unit with respect to the microlens array. In this way, the laser light source unit can irradiate, as combined light, laser light emitted from the plurality of laser diodes toward the front of the laser light source unit.

At that time, since the microlens array and the second condensing lens are supported on a common lens holder, it is possible to improve the accuracy of the positional relationship therebetween. Moreover, since the microlens array is supported on the lens holder via an array holder, it is possible to easily form the microlens array from a material such as synthetic quartz which is inferior in workability but excellent in optical characteristics. In this way, it is possible to broaden the range of selection for the type of each laser diode and its output.

In addition, a plurality of through-holes through which the light emitted from a plurality of first condensing lenses passes are formed in the array holder. Therefore, as compared to the case where the array holder is configured by a general annular member in which a single circular opening is formed, sufficient bonding margin can be secured when bonding the microlens array to the array holder. In this way, it is possible to sufficiently secure the support strength of the microlens array.

As described above, according to the disclosure, in the laser light source unit including a plurality of laser diodes, it is possible to sufficiently secure the support strength of the microlens array.

Further, according to the disclosure, a plurality of through-holes is formed in the array holder, so that it is possible to efficiently remove stray light included in the light emitted from a plurality of first condensing lenses. In particular, even when some of the plurality of first condensing lenses are detached, the occurrence of the stray light can be suppressed to the minimum.

In the above configuration, adjustment clearance for adjusting the position of the array holder in a direction orthogonal to a front and rear direction of the laser light source unit may be provided in a holder support portion of the lens holder for supporting the array holder. In this way, the microlens array can be aligned in a state where the microlens array supported on the array holder is positioned in the front and rear direction of the laser light source unit.

In the above configuration, the array holder may be supported on the holder support portion by adhesion fixation with an ultraviolet-curable adhesive and screw fastening. In this way, the microlens array can be securely supported by the lens holder.

In the above configuration, the plurality of laser diodes and the plurality of first condensing lenses may be supported on a common light source holder. In this way, the accuracy of the positional relationship therebetween can be improved. Moreover, the lens holder may be fixed to the light source holder in a state of being engaged with the light source holder so as to be slidable in the front and rear direction of the laser light source unit. In this way, it is possible to improve the accuracy of the positional relationship between the microlens array and the second condensing lens supported on the lens holder and the plurality of laser diodes and the plurality of first condensing lenses supported on the light source holder in the front and rear direction of the laser light source unit.

In the above configuration, the laser light source unit may include one or more mirrors configured to reflect the laser light emitted from some laser diodes of the plurality of laser diodes and transmitted through the first condensing lenses, and the one or more mirrors may be fixed to the light source holder. In this way, the plurality of laser diodes and the plurality of first condensing lenses can be easily arranged with good space efficiency.

At that time, the plurality of laser diodes may include four laser diodes arranged in a cross-shaped positional relationship around an irradiation reference axis of the laser light source unit, the one or more mirrors may include a pair of mirrors arranged on opposite sides of the irradiation reference axis, and two laser diodes of the four laser diodes may be arranged toward the front of the laser light source unit and the other two laser diodes may be arranged toward the pair of mirrors. In this way, the following operational effects can be obtained.

That is, a plurality of through-holes formed in the array holder can be arranged in the vicinity of the irradiation reference axis. Therefore, it is possible to secure larger adhesion margin for adhering the microlens array, and the support strength of the microlens array can be further improved.

What is claimed is:

1. A laser light source unit configured to be able to irradiate, as combined light, laser light emitted from a plurality of laser diodes toward front of the laser light source unit, the laser light source unit comprising:
a plurality of first condensing lenses configured to condense the laser light emitted from each of the plurality of laser diodes;
a microlens array disposed on a front side of the laser light source unit with respect to the plurality of first condensing lenses; and
a second condensing lens disposed on the front side of the laser light source unit with respect to the microlens array,
wherein the microlens array and the second condensing lens are supported on a common lens holder,
wherein the microlens array is supported on the lens holder via an array holder, and
wherein a plurality of through-holes through which light emitted from the plurality of first condensing lenses passes is formed in the array holder.

2. The laser light source unit according to claim 1,
wherein adjustment clearance for adjusting the position of the array holder in a direction orthogonal to a front and rear direction of the laser light source unit is provided in a holder support portion for supporting the array holder in the lens holder.

3. The laser light source unit according to claim 2,
wherein the array holder is supported on the holder support portion by adhesion fixation with an ultraviolet-curable adhesive and screw fastening.

4. The laser light source unit according to claim 1,
wherein the plurality of laser diodes and the plurality of first condensing lenses are supported on a common light source holder, and
wherein the lens holder is fixed to the light source holder in a state of being engaged with the light source holder so as to be slidable in the front and rear direction of the laser light source unit.

5. The laser light source unit according to claim 1,
wherein the laser light source unit comprises one or more mirrors configured to reflect the laser light emitted from some laser diodes of the plurality of laser diodes and transmitted through the first condensing lenses, and
wherein the one or more mirrors are fixed to the light source holder.

6. The laser light source unit according to claim 5,
wherein the plurality of laser diodes comprises four laser diodes arranged in a cross-shaped positional relationship around an irradiation reference axis of the laser light source unit,
wherein the one or more mirrors comprises a pair of mirrors arranged on opposite sides of the irradiation reference axis, and
wherein two laser diodes of the four laser diodes are arranged so as to face toward the front of the laser light source unit and the other two laser diodes are arranged so as to face toward the pair of mirrors.
